(19) United States
(12) Patent Application Publication
(10) Pub. No.: US 2003/0228529 A1
(43) Pub. Date: Dec. 11, 2003

(54) Photomask and method for repairing defects

(75) Inventors: Laurent Dieu, Austin, TX (US); Matthew J. Lamantia, Cedar Park, TX (US)

Correspondence Address: BAKER BOTTS L.L.P., PATENT DEPARTMENT, 98 SAN JACINTO BLVD., SUITE 1500, AUSTIN, TX, 78701-4039, US

(73) Assignee: DuPont Photomasks, Inc.

(21) Appl. No.: 10/457,315

(22) Filed: Jun. 9, 2003

Related U.S. Application Data
(60) Provisional application No. 60/387,375, filed on Jun. 10, 2002.

(51) Int. Cl. G03F 1/14; G03F 1/08; C23C 14/34

(52) U.S. Cl. 430/5; 204/192.11; 204/192.28

(57) ABSTRACT

A photomask and method for repairing defects on the same are disclosed. The photomask preferably includes a substrate, a buffer layer and a nontransmissive layer with the buffer layer disposed between the substrate and the nontransmissive layer. The method includes forming a pattern in the nontransmissive layer. If one or more defects are identified in the patterned nontransmissive layer, the buffer layer protects the substrate from damage when defects in the patterned nontransmissive layer are repaired.

### RELATED APPLICATIONS

This application claims the benefit of U.S. provisional patent application Serial No. 60/387,375 entitled “Photomask and Method For Repairing Defects On The Same” filed on Jun. 10, 2002.

### TECHNICAL FIELD OF THE INVENTION

This invention relates in general to the field of lithography and, more particularly, to a photomask and method for repairing defects on the same.

### BACKGROUND OF THE INVENTION

Today, photolithography generally requires short exposure wavelengths for successful imaging of very small semiconductor device dimensions on a wafer. At wavelengths in or below the deep ultraviolet (DUV) range, e.g., below two hundred nanometers, materials and techniques typically used to produce a photomask assembly have become increasingly important.

A typical fabrication process for a photomask may include imaging a circuit pattern into a resist layer, developing the resist layer, etching the resist layer and any uncovered regions of an opaque or semitransmissive layer and removing unetched portions of the resist layer. During the process, defects may be created if portions of the opaque or semitransmissive layer remain on the substrate in areas that should be free of such material. These defects may be repaired by removing the excess material but the substrate may be damaged during the repair process.

At least two techniques have previously been used to repair a photomask. Focused gallium ion beam photomask repair technology typically relies on ion detection to determine an endpoint for the defect repair process. In order to determine the endpoint, a substrate below the defect is sampled to detect the presence of gallium ions. Since sampling of the substrate does not indicate an endpoint until gallium ions are present in the substrate, undesired gallium contamination and/or pitting of the substrate may occur before the endpoint. Gallium contamination increasingly absorbs energy at wavelengths below 400 nm. Any associated damage to the substrate may be mitigated by reducing the dose of the ion beam and/or post processing after the ion beam repair process is complete. However, dose reduction may hinder overall quality of an image projected by the photomask and may reduce endpoint precision. Furthermore, post processing may result in localized phase errors. Repair techniques using focused Ga ion beam (such as Seiko—SIR3000x) may also have the drawback of possibly straining a transparent substrate.

Other repair techniques may use laser evaporation or ablation to remove defects. Laser repair techniques may cause divots in a substrate that can alter optical characteristics of the substrate and associated photomask. The endpoint for laser repair processes is often determined by the presence or absence of ions associated with removal of a defect. The endpoint for repair of nontransmissive material disposed on a substrate is often more difficult to determine if the nontransmissive material and the substrate have common ions. The presence of common ions in materials used to form an nontransmissive layer and an associated substrate often results in substrate damage in the form of quartz pits.

Substrate damage was often not a concern in lithography systems using exposure wavelengths above approximately four hundred nanometers. However, in lithography systems using exposure wavelengths below approximately four hundred nanometers, substrate damage may cause absorption of such exposure wavelengths and thus, decrease transmissive properties of an associated photomask.

TiSi-nitride based materials have previously been used to form embedded, attenuated phase shift photomask blanks and associated photomasks. Such materials are sometimes referred to as silicon nitride titanium nitride (SiNTiN). Silicon nitride (Si₃N₄)is a dielectric material frequently used in the semiconductor industry.

### SUMMARY OF THE INVENTION

In accordance with teachings of the present invention, disadvantages and problems associated with repairing defects on a photomask have been substantially reduced or eliminated. For one embodiment, a photomask may be formed with a buffer layer that prevents an associated substrate from being damaged during a repair process. The buffer layer may also prevent electrostatic discharge (ESD) damage to the associated substrate. Another embodiment of the present invention may include a method for repairing defects on a photomask having a buffer layer and a nontransmissive layer formed on a substrate with the buffer layer disposed between the nontransmissive layer and the substrate. A pattern may be formed in the nontransmissive layer. If one or more defects are identified in the patterned nontransmissive layer, the defects may be repaired in the patterned nontransmissive layer while the buffer layer protects the substrate from damage during the repair process.

A further embodiment of the present invention may include a photomask assembly having a photomask pellicle assembly defined in part by a pellicle frame and a pellicle film attached to the pellicle frame. The photomask assembly may also include a photomask coupled to the pellicle assembly opposite from the pellicle film. The buffer layer may be used to protect the substrate from damage during repair of any defects in the nontransmissive layer. After repair of the nontransmissive layer, portions of the buffer layer corresponding with a pattern formed in the nontransmissive layer may be etched to expose adjacent portions of the substrate. The resulting patterned layer may be defined in part by etched portions of the nontransmissive layer and corresponding etched portion of the buffer layer.

In accordance with teachings of the present invention, a photomask may be formed with a buffer layer disposed on at least a portion of an associated substrate. The buffer layer may be formed from various materials which transmit, partially transmit, absorb and/or reflect electromagnetic energy. The photomask may further include a nontransmissive layer formed on the buffer layer. The nontransmissive layer may be formed from various materials which absorb, partially transmit, and/or reflect electromagnetic energy. A pattern may be formed in the nontransmissive layer using various lithography techniques. The buffer layer is preferably operable to prevent the substrate from being damaged during a repair process associated with the patterned nontransmissive layer.

Technical advantages of certain embodiments of the present invention may include a buffer layer that prevents a substrate of a photomask from being damaged during a repair process. During a photomask manufacturing process, defects may be formed in a nontransmissive layer and must be repaired. During the repair process, a repair beam may be used to remove such defects. Since the buffer layer is preferably located between the nontransmissive layer and the substrate, any damage from the repair process will generally effect only the buffer layer rather than the substrate.

Another technical advantage of certain embodiments of the present invention may include a buffer layer that reduces electrostatic discharge (ESD) damage during a manufacturing process. Traditionally, oxide materials have been used as a buffer material since oxide materials will typically remain intact during an etch of an associated nontransmissive layer. However, many oxide materials may also function as an insulator, which increases the risk of ESD damage by providing a dielectric material between a charged nontransmissive layer and an associated substrate. Accordingly, the present invention reduces the risk of ESD damage by using electrically conductive materials to form the buffer layer.

A further technical advantage of certain embodiments of the present invention may include a buffer layer that enables precise endpoint detection of a repair process using a focused ion beam (FIB) system to repair any damage to a nontransmissive layer. The buffer layer may be formed from material that is different from material used to form the nontransmissive layer. During an ion beam repair process, an associated repair tool may monitor the concentration of ions associated with the ion beam in the nontransmissive layer. The endpoint of the repair process may be determined when no ions associated with the ion beam are detected in the nontransmissive layer since the ion concentration will change when the defect has been removed and the ion beam reaches the surface of the buffer layer.

Other aspects of the present invention include using single ion beam deposition or dual ion beam deposition techniques to fabricate at least portions of an attenuating, embedded phase shift photomask blank capable of producing approximately one hundred eighty degree (180°) phase shifts at selected lithographic wavelengths less than four hundred (400) nanometers (nm). For some applications the phase shifts may vary plus or minus five degrees (±5°).

All, some, or none of these technical advantages may be present in various embodiments of the present invention. Other technical advantages will be readily apparent to one skilled in the art from the following figures, descriptions, and claims.

### BRIEF DESCRIPTION OF THE DRAWINGS

A more complete and thorough understanding of the present invention and advantages thereof may be acquired by referring to the following description taken in conjunction with the accompanying drawings, in which like reference numbers indicate like features, and wherein:

FIG. 1 is a schematic drawing in section showing one example of a photomask assembly formed according to teachings of the present invention;

FIG. 2A is a schematic drawing in section with portions broken away showing one example of a photomask blank which may be used to form a photomask and/or photomask assembly in accordance with teachings of the present invention;

FIGS. 2B, 2C and 2D are schematic drawings in section with portions broken away showing various views of a photomask formed from the photomask blank of FIG. 2A before and after a repair process has removed defects from a patterned layer according to teachings of the present invention; and

FIGS. 3A and 3B are schematic drawings in section showing one example of a photomask repaired by an ion beam repair process according to teachings of the present invention.

### DETAILED DESCRIPTION OF THE INVENTION

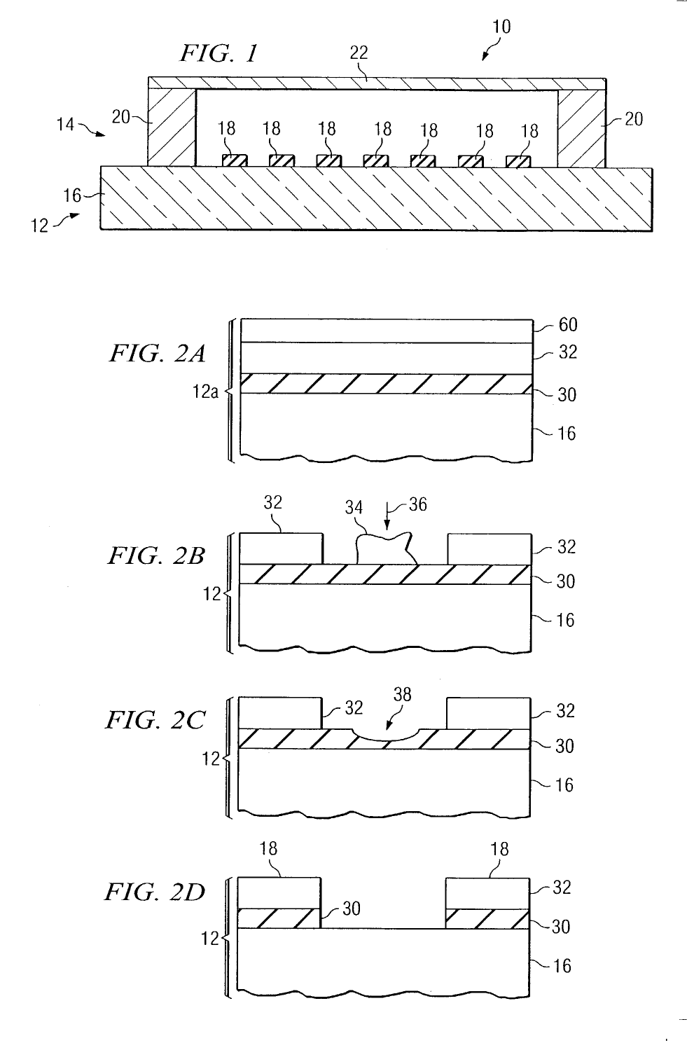

Preferred embodiments of the present invention and its advantages may be understood by reference to FIGS. 1 through 3B, where like numbers are used to indicate like and corresponding parts.

FIG. 1 illustrates a cross-sectional view of photomask assembly 10 with photomask 12 coupled to pellicle assembly 14. Substrate 16 and patterned layer 18 cooperate with each other to form photomask 12, otherwise known as a mask or reticle. Photomask 12 may have a variety of sizes and shapes, including, but not limited to, round, rectangular or square. Photomask 12 may also be any variety of photomask types, including, but not limited to, a one-time master, a five-inch reticle, a six-inch reticle, a nine-inch reticle or any other appropriately sized reticle that may be used to project an image of a circuit pattern onto a semiconductor wafer (not expressly shown). Photomask 12 may further be a binary mask, a phase shift mask, an optical proximity correction (OPC) mask, or any other type of mask suitable for use in a lithography system. When photomask assembly 10 is placed in a lithography system, a circuit image defined in part by patterned layer 18 may be projected through substrate 16 and on to the surface of a semiconductor wafer.

For some applications, substrate 16 may be a transparent material such as quartz, synthetic quartz, fused silica, magnesium fluoride (MgF₂), calcium fluoride (CaF₂), or any other suitable material that transmits at least approximately seventy-five percent (75%) of incident light having a wavelength between approximately ten (10) nanometers (nm) and approximately 450 nm. In an alternative embodiment, substrate 16 may be a reflective material such as silicon or any other suitable materials that reflect greater than approximately fifty percent of incident light having a wavelength between approximately 10 nm and 450 nm.

In some embodiments, patterned layer 18 may be a metal material such as chrome, chromium nitride, a metallic oxy-carbo-nitride (M-O—C—N), where the metal is selected from the group consisting of chromium, cobalt, iron, zinc, molybdenum, niobium, tantalum, titanium, tungsten, aluminum, magnesium and silicon, and any other suitable material that absorbs and/or reflects electromagnetic energy with wavelengths in the ultraviolet (UV) range, deep ultraviolet (DUV) range, vacuum ultraviolet (VUV) range and extreme ultraviolet range (EUV). In an alternative embodiment, patterned layer 18 may be a partially transmissive material, such as molybdenum silicide (MoSi), which has a transmissivity of approximately one percent to approximately thirty percent in the UV, DUV, VUV and EUV ranges.

In other embodiments, patterned layer 18 may include at least one nontransmissive layer formed on at least one buffer layer. The nontransmissive layer and the buffer layer may have any of the transmissive characteristics described above in reference to patterned layer 18. The buffer layer preferably prevents damage from occurring to substrate 16 during a defect repair process associated with the nontransmissive layer.

Frame 20 and pellicle film 22 cooperate with each other to form pellicle assembly 14. Pellicle film 22 may be a thin film membrane formed of a material such as nitrocellulose, cellulose acetate, an amorphous fluoropolymer, such as Teflon® AF manufactured by E. I. du Pont de Nemours and Company or Cytop manufactured by Asahi Glass, or another suitable UV, DUV, VUV or EUV film. Pellicle film 22 may be prepared by conventional techniques such as spin casting. Frame 20 is typically formed of anodized aluminum. Alternatively, frame 20 be formed of stainless steel, plastic or other suitable materials.

Pellicle film 22 protects photomask 12 from dust particles by ensuring that the dust particles remain a defined distance away from photomask 12. This may be especially important in a lithography system. During a lithography process, photomask assembly 10 is exposed to electromagnetic energy produced by a radiant energy source within the lithography system. The electromagnetic energy may include light of various wavelengths, such as wavelengths approximately between the I-line and G-line of a Mercury arc lamp, or DUV, VUV or EUV light. In operation, pellicle film 22 is preferably designed to allow a large percentage of incident electromagnetic energy to pass therethrough. Dust particles collected on pellicle film 22 will likely be out of focus on the surface of a wafer being processed using photomask assembly 10 and, therefore, the exposed image on the wafer (not expressly shown) should be clear.

Photomask 12 may be fabricated from a photomask blank that includes a layer of buffer material, a layer of nontransmissive material and a layer of resist material disposed on one surface of substrate 16. One example is shown in FIG. 2A. For some applications, the buffer layer and the nontransmissive layer may be formed from multiple layers of material. Respective layers of buffer material, nontransmissive material, and resist material may be deposited on one surface of substrate 16 using physical vapor deposition (PVD), chemical vapor deposition (CVD), ion beam deposition (IBD), dual ion beam deposition (DIBD) or any other suitable deposition technique.

Photomask 12 may be formed from a photomask blank using various lithography processes. In a typical lithography process, a mask pattern file (not expressly shown) that includes data for patterned layer 18 may be generated from a circuit design pattern (not expressly shown). The desired pattern for patterned layer 18 may be imaged into a resist layer of the photomask blank using a laser, electron beam, X-ray lithography tool or other suitable source of electromagnetic energy. For example, a laser lithography tool may use an Argon-Ion laser that emits light having a wavelength of approximately 364 nanometers (nm). In alternative embodiments, a laser lithography tool may use laser emitting light at wavelengths from approximately 150 nm to approximately 300 nm.

As discussed later in more detail with respect to FIGS. 2A-2D, an imaged pattern (not expressly shown) may be imaged on a resist layer. The resist layer and an associated nontransmissive layer may be etched to create at least a portion of corresponding etched pattern 18. One or more defects (not expressly shown) which may occur in patterned layer 18 may be repaired in accordance of teachings of the present invention without damaging substrate 16.

FIGS. 2A, 2B, 2C and 2D illustrate cross-sectional views of photomask blank 12a and associated photomask 12. FIG. 2A shows photomask blank 12a prior to forming patterned layer 18 associated with photomask 12. FIGS. 2B, 2C and 2D show examples of some steps associated with repairing a defect in patterned nontransmissive layer 32 in accordance with teachings of the present invention.

Photomask 12 may be a phase shift mask (PSM), including, but not limited to, an alternating PSM, an attenuated PSM, and a multitone PSM. For some applications, photomask 12 may be formed from an embedded, attenuated phase shift photomask blank 12a. For some applications photomask blank 12a may be generally described as an embedded, attenuated phase shift photomask blank with repair buffer, etch control and electrostatic discharge (ESD) reducing layer 30. However, the present invention is not limited to phase shift photomasks.

In FIG. 2A, photomask blank 12a is shown after buffer layer 30, nontransmissive layer 32 and resist layer 60 have been formed on one surface of substrate 16. Substrate 16 may be formed from transparent material, such as quartz, synthetic quartz or fused silica, or reflective material, such as silicon. Various lithography fabrication techniques may be used to form photomask blank 12a with layers 30, 32 and 60.

Materials used to fabricate layers 30, 32 and/or 60 on photomask blank 12a may be homogeneous, graded or multilayered as long as photomask blank 12a satisfies optical properties of a semitransparent medium providing desired transmission and phase shift characteristics. The structure of photomask blank 12a will generally have application for lithographic processes using wavelengths below 400 nm. For example some lithography processes use electromagnetic energy with wavelengths of 248 nm, 193 nm, 157 nm, 100 nm, and 50 nm.

Buffer layer 30 may act as a protective layer so that substrate 16 is not damaged during a repair process associated with nontransmissive layers 32. Buffer layer 30 may also serve as an etch stop during etching processes associated with patterning of nontransmissive layer 32. Materials used to form buffer layer 30 may be selected to enhance phase and transmission percentage uniformity of nontransmissive layer 32. Furthermore, buffer layer 30 may be formed at least in part from conductive materials to reduce electrostatic discharge (ESD) effects on substrate 16 during fabrication of photomask blank 12a, photomask 12 and/or photomask assembly 10.

Buffer layer 30 may be formed from any material that offers dry etch selectivity relative to both substrate 16 and nontransmissive layer 32. Materials used to form buffer lay 30 preferably have optical properties that do not interfere with and preferably enhance overall optical characteristics of photomask 12. The thickness of buffer lay 30 may vary in thickness between a few angstroms to a few nanometers depending on respective photomask repair technology used during manufacture of photomask 12. The thickness of buffer layer 30 is preferably selected to minimize or prevent any straining of substrate 16.

For some applications buffer layer 30 will preferably be formed from carbon type materials such as “Diamond Like Carbon” (DLC) because most commercially available dry etch processes associated with fabrication of embedded, attenuated phase shift photomasks will not etch DLC materials. Thus, DLC materials generally have good dry etch selectivity relative to materials used to form embedded, attenuated phase shift photomasks. In a second etch process, DLC materials preferably have good selectivity relative to substrate 16. DLC materials often have very good electrical properties which prevent as critical dimensions become smaller (under 500 nm).

Hard carbon films or layers may sometimes be described as diamond like carbon (DLC) films or layers. DLC materials may be generally described as a mixture of diamond and graphite structures including, but not limited to, hard noncrystal carbon, hard amorphous carbon, amorphous carbon and i-carbon. A wide variety of DLC materials are commercially available for use in forming one or more layers 30 on photomask blank 12a. However, the present invention is not limited to buffer layers formed from DLC materials.

Layers 30 and 32 of photomask blank 12a may be formed from materials such as:

Mₐ-SiₓO_{y}N_{z} disposed in either a generally homogeneous or graded structure, where M is a metal from Group IV, V or VI; or

M₁OₐN_{b}/M₂O_{c}N_{d} multilayers having at least one layer of each. M₁ may be aluminum or silicon and “a” varies between (0 to 1) while “b” varies between (0 and 1-a). M₂ is a metal from Group IV, V or VI.

Layers 30 and 32 may be a combination of the above materials so that layer 32 functions as a nontransmissive layer and layer 30 functions as a buffer for substrate 16.

Alternatively, layers 30 and 32 may be generally homogeneous or graded structures of MSiₓO_{y}N_{z} where M is a metal selected from Groups IV, V or VI or a multilayer structure of M₁OₐN_{b}/M₂O_{c}N_{d} where M₁ is either aluminum (Al) or silicon (Si), M₂ is a metal from Group IV, V or IV, and a varies between 0 and 1 while b varies between 0 and 1-a. The multilayered structure may be a combination of the above materials such that at least one layer 32 is nontransmissive to the exposure wavelength and another layer 30 function as a buffer to protect an associated substrate. The resulting structure may be capable of producing a 180° phase shift at selected exposure wavelengths in a lithography system of less than 400 nanometers.

Buffer layer 30 may be formed from materials other than those used to form nontransmissive layer 32 to provide an etch stop for repair of defects in layer 32. A repair tool may monitor a repair site for either the elimination of ions from nontransmissive material associated with the defect or for the presence of ions from the buffer layer material disposed below the defect. Once the stop condition is achieved the repair may be deemed complete. For example: An FIB repair tool may monitor for Si ions from a defect associated with a nontransmissive layer formed from SiNTiN material. Without buffer layer 30 the difference between ion yield of the SiNTiN defect and a substrate formed in part with silicon (Si) is typically too small to accurately define an end point. The Si yield from buffer layer 30 made of DLC materials would yield substantially zero Si ions. Thus, an end point for removing a defect associated with nontransmissive layer 32 may be defined more precisely by buffer layer 30 blocking or preventing production of secondary Si ions from substrate 16.

Buffer layer 30 and nontransmissive layer 32 may be deposited using PVD, CVD, IBD or any other suitable deposition technique while simultaneously receiving a thermal treatment. In one embodiment, a single ion beam deposition (IBD) process may be used to deposit one or more buffer layers 30 and one or more nontransmissive layers 32. The resulting photomask blank may be an attenuating embedded phase shift photomask blank capable of producing 180° phase shifts at selected lithographic wavelengths less than 400 nanometers. The process may include depositing at least one buffer layer 30 and at least one nontransmissive layer 32 or a combination thereof, on substrate 16 by ion beam sputtering of a target or targets by ions from a group of gases.

In a single IBD process, a plasma discharge may be contained in a separate chamber (ion “gun” or source) and ions extracted and accelerated by an electric potential impressed on a series of grids at the “exit port” of the gun (not expressly shown). The IBD process may also provide a cleaner process (fewer added particles) at the deposition surface on substrate 16 because the plasma that traps and transports charged particles to substrate 16 is generally not in proximity with either buffer layer 30 or nontransmissive layer 32. Additionally, the IBD process generally operates at lower total gas pressure which results in reduced levels of chemical contamination. The IBD process also has the ability to independently control deposition flux and reactive gas ion flux (current) and energy.

During the single IBD process, an energized beam of ions (usually neutralized by an electron source) may be directed from a deposition gun (not expressly shown) to a target material located on a target holder. The target material is typically sputtered when bombarding ions have energy above a sputtering threshold energy for the specific material, which may be approximately fifty (50) eV. Ions from the deposition gun may be from an inert gas source such as He, Ne, Ar, Kr, Xe, although reactive gases such as O₂, N₂, CO₂, F₂, CH₃, or combinations thereof, may also be used. When these ions are from an inert gas source, the target material may be sputtered and deposited as either nontransmissive layer 32 on buffer layer 30 or buffer layer 30 on substrate 16. When these ions are produced by a reactive gas source, the ions may combine with the target material. Products of the chemical combination may be sputtered or deposited as either nontransmissive layer 32 on buffer layer 30 or buffer layer 30 on substrate 16.

In a dual IBD process, ions from a second or “assist” gun (not expressly shown) are typically neutralized by an electron source directed at the surface of buffer layer 30 or substrate 16. An ion beam from a first gun or deposition gun may also be directed at substrate 16 or buffer layer 30 similar to a single IBD process. The ions from the assist gun may originate from a reactive gas source such as O₂, N₂, CO₂, F₂, N₂O, H₂O, NH₃, CF₄, CHF₃, CH₄, C₂H₂, or any combination thereof. The energy of ions from the assist gun is usually lower than the energy of ions from the deposition gun. The assist gun provides an adjustable flux of low energy ions that react with sputtered atoms from the deposition gun at the surface of buffer layer 30 or substrate 16 to respectively form nontransmissive layer 32 or buffer layer 30. In a dual ion beam deposition (DIBD) process the angles between a material target, substrate 16, and associate deposition gun and assist gun (not expressly shown) may be adjusted to optimize film uniformity and film stress.

One example of a dual IBD process includes using a deposition gun to deposit at least one layer of optically transmitting material and at least one layer of optically absorbing material or a combination thereof, on substrate 16 by ion beam sputtering of a primary target by ions from a group of gases. An assist gun may also deposit portions of the at least one layer of optically transmitting material and the at least one layer of optically absorbing material, or a combination thereof, on substrate 16 by a secondary ion beam of a group of gases. The layers may be formed either directly, or by a combination of the gas ions from the assist gun and material deposited from the primary target on the substrate.

Another example of a dual IBD process for preparing an embedded, attenuated phase shift photomask blank capable of producing 180° phase shift at selected lithographic wavelengths less than 400 nanometers includes:

depositing at least one layer of optically transmitting material and at least one layer of optically absorbing material or a combination thereof, on substrate 16 by ion beam sputtering of a target or targets by ions from a group of gases; and

bombarding substrate 16 by a secondary ion beam from an assist source with ions from a reactive gas wherein the reactive gas is at least one gas selected from the group consisting of N₂, O₂, CO₂, N₂O, H₂O, NH₃, CF₄, CHF₃, F₂, CH₄, and C₂H₂.

After photomask blank 12a has been formed as shown in FIG. 2A, a circuit design pattern may be imaged onto resist layer 60 using various lithographic techniques. Resist layer 60 may then be developed and exposed areas of resist layer 60 and adjacent portions of nontransmissive layer 32 etched to form a corresponding pattern in nontransmissive layer 32. Any undeveloped portions of resist layer 60 may be removed as shown in FIG. 2B. Any defects which may be formed in nontransmissive layer 32 during the patterning process may be repaired in accordance with teachings of the present invention.

Nontransmissive layer 32 may include one or more defects 34 such as shown in FIG. 2B that were not removed during one or more etch processes associated with patterning nontransmissive layer 32. Each defect 34 may be removed or repaired using repair beam 36. Repair beam 36 may be a focused ion beam (FIB) that uses ion detection in buffer layer 30 to determine an endpoint for the repair process. A laser (not expressly shown) that evaporates or ablates material or any other suitable technique may also be used to repair nontransmissive layer 32 by removing defect 34.

As shown in FIG. 2C, repair beam 36 may damage portions of buffer layer 30 directly below defect 34. In the illustrated embodiment, repair beam 34 creates damaged portion 38 in buffer layer 30. Damaged portion 38 may be gallium contamination and/or pitting created by FIB beam 36. Damaged portions 38 may also be a divot created by a laser or any other type of damage created by an associated repair process.

As illustrated in FIG. 2D, once defect 34 has been removed from nontransmissive layer 32, portions of buffer layer 30 may be removed from substrate 16 in uncovered areas or patterned areas of nontransmissive layer 32 to expose adjacent portions of substrate 16. In one embodiment, portions of buffer layer 30 may be removed with a dry etch process that is different from the etch process or processes associated with patterning nontransmissive layer 32. The resulting photomask 12 includes substrate 16 and patterned layer 18 defined in part by one or more buffer layers 30 and one or more nontransmissive layers 32 is shown in FIG. 20.

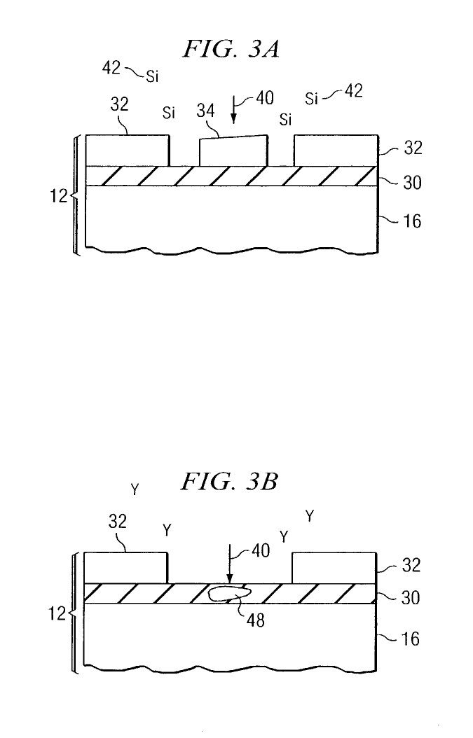

FIGS. 3A and 3B illustrate cross-sectional views of photomask 12 before and after repair by an FIB process. As illustrated in FIG. 3A, photomask 12 includes buffer layer 30 formed between nontransmissive layer 32 and substrate 16. In one embodiment, nontransmissive layer 32 may be formed from SiNTiN based materials or any other suitable material that has appropriate transmissive characteristics or reflective characteristics when exposed to electromagnetic energy with a wavelength between approximately 10 nm and approximately 450 nm. Buffer layer 30 may be formed from diamond like carbon (DLC) materials or any other material that does not change optical characteristics of photomask 12 and has suitable dry etch selectivity relative to nontransmissive layer 32 and substrate 16. For some applications, buffer layer 30 may have a thickness between approximately one hundred angstroms (100 Å) and three nanometers (3 nm) depending on respective repair processes used to remove any defects in nontransmissive layer 32.

For one embodiment, buffer layer 30 may be made of DLC material with a thickness of approximately 150 angstroms. Nontransmissive layer 32 may be formed from SiNTiN based materials with a thickness of approximately six hundred thirty (630) angstroms. The combination of such materials may produce photomask 12 with approximately six percent transmission and a phase shift of approximately 180°±5° at an exposure wavelength of approximately 193 nanometers.

Focused ion beam (FIB) 40 may be used in a repair tool (not expressly shown) to remove defect 34. Buffer layer 30 can be used to protect substrate 16 from gallium contamination. The required thickness of buffer layer 30 may be a function of the material used to form layer 30 and the associated FIB process. The thickness of layer 30 may be proportional to the acceleration voltage and the overall dose per pixel of FIB 40.

During the repair process, silicon ions 42 may be produced as FIB 40 removes defect 34. As illustrated in FIG. 3B, silicon ions 42 may not be present when defect 34 has been completely removed. The repair tool (not expressly shown), may monitor the concentration of silicon ions 42 to determine an end point for the repair process. When no silicon ions 42 are present, the repair tool may determine that defect 34 has been completely removed. Buffer layer 30, therefore, provides a technique for determining the endpoint of the repair process in order to minimize possible damage to substrate 16 caused by FIB 40. Furthermore, buffer layer 30 protects substrate 16 during the repair process because FIB 40 damages buffer layer 30 instead of substrate 16. See for example defect 48 in buffer layer 30.

Optical Properties

DLC

n(193)=1.757 k(193)=0.318

SiNTiN

n(193)=2.356 k(193)=0.5

Using the following Equations:

Phase=(2 Pi/λ)×Thickness×(n_{Material}−1)

Tₛ≈(1−R)²exp(−4πkₛdₛ/λ)

Although the present invention has been described in detail, it should be understood that various changes, substitutions, and alterations can be made without departing from the spirit and scope of the invention.

What is claimed is:

1. A method for repairing defects on a photomask, comprising:
forming a buffer layer on one surface of a substrate associated with the photomask;
forming a nontransmissive layer on the buffer layer;
forming a pattern in the nontransmissive layer with the buffer layer disposed between the substrate and the nontransmissive layer;
identifying one or more defects in the patterned nontransmissive layer; and
repairing at least one of the defects in the patterned nontransmissive layer while the buffer layer protects the substrate from damage during the repair step.

2. The method of claim 1, further comprising:
etching portions of the buffer layer which were uncovered by forming the pattern in the nontransmissive layer; and
forming substantially the same pattern in the buffer layer as formed in the nontransmissive layer by etching the uncovered portions of the buffer layer.

3. The method of claim 1, further comprising forming the buffer layer from a carbon compound.

4. The method of claim 1, further comprising forming the buffer layer from a diamond like carbon material (DLC).

5. The method of claim 1, further comprising forming the buffer layer with a thickness between approximately one hundred angstroms and three nanometers.

6. The method of claim 1, further comprising forming the nontransmissive layer with a multilayer structure.

7. The method of claim 1, further comprising forming the nontransmissive layer with a graded structure.

8. The method of claim 1, further comprising forming the nontransmissive layer from silicon nitrite and titanium nitride.

9. The method of claim 1, wherein forming the pattern in the nontransmissive layer the photomask comprises:
forming a resist layer on the nontransmissive layer opposite from the buffer layer;
imaging the pattern in the resist layer formed on the nontransmissive layer;
developing regions of the resist layer corresponding to the imaged pattern; and
etching the developed regions of the resist layer to form the pattern in the nontransmissive layer.

10. The method of claim 1, further comprising controlling an endpoint of the repair step with the buffer layer.

11. The method of claim 1, further comprising forming the nontransmissive layer at least in part from material selected from the group consisting of absorbent material, reflective material, opaque material and partially transmissive material.

12. A photomask assembly, comprising:
a pellicle assembly defined in part by a pellicle frame and a pellicle film attached thereto;
a photomask coupled to the pellicle assembly opposite from the pellicle film;
the photomask having a patterned layer defined in part by a pattern formed in a nontransmissive layer and a corresponding pattern formed in a buffer layer;
the buffer layer disposed between the nontransmissive layer and one surface of a substrate;
the buffer layer operable to protect the substrate from being damaged during repair of one or more defects in the patterned nontransmissive layer; and
uncovered portions of the buffer layer removed to expose portions of the substrate corresponding with the patterned nontransmissive layer.

13. The assembly of claim 12, wherein the buffer layer comprises a carbon compound.

14. The assembly of claim 12, wherein the buffer layer comprises diamond like carbon (DLC).

15. The assembly of claim 12, further comprising the buffer layer having a thickness of between approximately one hundred angstroms and three nanometers.

16. The assembly of claim 12, wherein the absorber layer comprises a multilayer structure.

17. The assembly of claim 12, wherein the nontransmissive layer is graded.

18. The assembly of claim 12, wherein the nontransmissive layer comprises silicon nitrite and titanium nitride.

19. The assembly of claim 12, further comprising the buffer layer operable to control an endpoint of the repair step.

20. The assembly of claim 12, further comprising the buffer layer operable to transmit an exposure wavelength of a lithography system.

21. A photomask, comprising:
a substrate;
a buffer layer formed on at least a portion of the substrate;
a nontransmissive layer formed on the buffer layer; and
the buffer layer operable to prevent the substrate from being damaged during a repair process associated with the nontransmissive layer.

22. The photomask of claim 21, wherein the buffer layer comprises a carbon compound.

23. The photomask of claim 21, wherein the buffer layer comprises diamond like carbon (DLC).

24. The photomask of claim 21, further comprising the buffer layer having a thickness between approximately one hundred angstroms and three nanometers.

25. The photomask of claim 21, wherein the nontransmissive layer comprises a multilayer structure.

26. The photomask of claim 21, wherein the nontransmissive layer is graded.

27. The photomask of claim 21, wherein the nontransmissive layer comprises silicon nitrite and titanium nitride.

28. The photomask of claim 21, further comprising the buffer layer operable to control an endpoint of the repair process.

29. A method of fabricating an embedded, attenuated phase shift photomask blank capable of producing approximately one hundred eight degree phase shifts at lithographic wavelengths less than four hundred nanometers, the method comprising:
depositing at least one layer of optically transmitting material which may be etched by a first process and at least one layer of nontransmissive material which may be etched by a second process on a substrate using a first ion beam to sputter of a primary target by ions from a first group of gases;
depositing the at least one layer of optically transmitting material and the at least one layer of nontransmissive material, or a combination thereof, on the substrate by a secondary ion beam from an assist source of a second group of gases; and
forming the respective layers using the gas ions from the assist source and gas ions by the first ion beam deposited on the substrate.

30. The method of claim 29 further comprising:
depositing the at least one layer of optically transmitting material and the at least one layer of nontransmissive material, or a combination thereof, on a substrate, by the first ion beam sputtering of the target by ions from the first group of gases; and
bombarding the substrate by the secondary ion beam from the assist source with ions from a reactive gas wherein the reactive gas includes at least one gas selected from the group consisting of N₂, O₂, CO₂, N₂O, H₂O, NH₃, CF₄, CHF₃, F₂, CH₄, and C₂H₂.
